(19) United States
(12) Patent Application Publication
(10) Pub. No.: US 2007/0126109 A1
(43) Pub. Date: Jun. 7, 2007

(54) Semiconductor device, manufacturing method for semiconductor device, electronic component, circuit board, and electronic device

(75) Inventor: Nobuaki Hashimoto, Suwa (JP)

Correspondence Address: HARNESS, DICKEY & PIERCE, P.L.C., P.O. BOX 828, BLOOMFIELD HILLS, MI, 48303, US

(73) Assignee: Seiko Epson Corporation

(21) Appl. No.: 11/633,106

(22) Filed: Dec. 1, 2006

(30) Foreign Application Priority Data
Dec. 6, 2005 (JP) 2005-351631

(51) Int. Cl. H01L 23/48

(52) U.S. Cl. 257/690

(57) ABSTRACT

A semiconductor device, includes: a semiconductor substrate having an active face; a first electrode provided on or above the active face of the semiconductor substrate; an external connection terminal electrically connected to the first electrode and provided on or above the active face of the semiconductor substrate; and a connection terminal provided on or above the active face of the semiconductor substrate, wherein any of a gold plated film, a silver plated film, and a palladium plated film is formed on at least one of the external connection terminal and the connection terminal.

### CROSS-REFERENCE TO RELATED APPLICATION

This application claims priority from Japanese Patent Application No. 2005-351631, filed Dec. 6, 2005, the contents of which are incorporated herein by reference.

### BACKGROUND

1. Technical Field

The present invention relates to a semiconductor device, a manufacturing method for a semiconductor device, an electronic component, a circuit board, and an electronic device.

2. Related Art

Bare-chip packaging is ideal for the high-density packaging of a semiconductor device.

However, the bare-chip has problems in that it is difficult to ensure its quality, to handle it, and so on.

Thus, semiconductor devices applied with chip scale package (CSP) have been developed.

Recently, in particular, as disclosed in Domestic Re-publication of PCT International Publication for Patent Application No. 01/071805 and Japanese Unexamined Patent Application, First Publication No. 2004-165415, a wafer level CSP (W-CSP), in which a CSP is formed at a wafer level, has received attention.

In a wafer level CSP, a plurality of semiconductor elements (integrated circuits) provided with a relocated wiring are formed on a wafer unit basis, and the wafer is cut into each semiconductor element to obtain individual semiconductor devices.

In many cases, the semiconductor device mentioned above is connected with an external structure by bonding wires or solder balls.

Electrodes to which the wires or the solder balls are connected include laminated-layer electrodes in which a nickel layer is formed on top of the copper foil of the circuit pattern and a gold layer is further formed on top of the nickel layer by techniques such as displacement plating, electroless reduction plating, or electroplating.

In the manufacturing process of such a semiconductor device, with regard to the heat curing process of an adhesive for fixing a semiconductor bare-chip to a circuit board, the following problem has been revealed.

That is, heat added during the heat curing of the adhesive allows the nickel to be released from the top surface of the nickel layer to diffuse in the gold layer thereon, resulting in deposition on the surface of the gold layer (i.e., on portions exposed to the atmosphere) in the form of nickel compounds (mainly a nickel hydroxide).

Furthermore, as disclosed in Japanese Unexamined Patent Application, First Publication No. 2005-223088, a phosphorus-enriched layer may be formed on the surface of the gold layer in the case in which nickel-phosphorus alloy plating is used instead of nickel plating.

When the surface of the gold layer in such a state is subjected to wire bonding or soldering, the above-mentioned compounds between the bonding wires or the solder balls and the gold layer prevents the junction of the two, thus reducing the junction strength.

Accordingly, for securing sufficient junction strength, a method is conceived in which the top surface of the gold layer is thinly removed to eliminate a nickel hydroxide component or the like.

However, such conventional techniques have problems such as the following.

An additional process of etch cleaning, or the like, is required after formation of the gold layer, thereby bringing about decreased efficiency in the manufacture of semiconductor devices.

### SUMMARY

An advantage of some aspects of the invention is to provide a semiconductor device, a manufacturing method for a semiconductor device, an electronic component, a circuit board, and an electronic device, in which the semiconductor device has electrodes that can obtain sufficient junction strength without bringing about decreased manufacturing efficiency.

A first aspect of the invention provides a semiconductor device, including: a semiconductor substrate having an active face; a first electrode provided on or above the active face of the semiconductor substrate; an external connection terminal electrically connected to the first electrode and provided on or above the active face of the semiconductor substrate; and a connection terminal provided on or above the active face of the semiconductor substrate, wherein any of a gold plated film, a silver plated film, and a palladium plated film is formed on at least one of the external connection terminal and the connection terminal.

Accordingly, the semiconductor device of the first aspect of the invention can suppress diffusion of the metal that forms an external connection terminal and a connection terminal as in the case in which a nickel layer or the like is used. Therefore, necessity for additional process of thinly removing the top surface is eliminated, thus preventing decrease in manufacturing efficiency.

Furthermore, according to the first aspect of the invention, the connection terminal provided in addition to an external connection terminal can be used for mechanical or electrical connection with, for instance, another functional structure (a functional structure different from that to which the external connection terminal is connected).

With this configuration, it is possible to integrate the semiconductor device and the functional structure into an electronic component, thus miniaturizing the electronic component.

It is preferable that, in the semiconductor device of the first aspect of the invention, any of the gold plated film, the silver plated film, and the palladium plated film be formed by electroless plating.

Thus, it is possible for the semiconductor device of the first aspect of the invention to realize a high-density interconnection because there is no need for an interconnection for electroplating.

It is preferable that the semiconductor device of the first aspect of the invention further include: relocated wiring provided on or above the active face and electrically connecting the first electrode with the external connection terminal.

With this configuration, it is possible to allow a free (optional) design of positioning or layout of an external connection terminal.

It is preferable that the semiconductor device of the first aspect of the invention further include: a second electrode provided on or above the active face of the semiconductor substrate and electrically connected with the connection terminal.

With this configuration, it is possible to perform electrical processing of the semiconductor device using the connection terminal.

Furthermore, it is possible for the semiconductor device to function, for example, as a driving element for the functional structure by electrically connecting this semiconductor device with the functional structure using the connection terminal.

It is preferable that, in the semiconductor device of the first aspect of the invention, the connection terminal be used for an electrical checkup or adjustment.

In other words, the connection terminal may be a terminal for use in maintenance such as an electrical checkup or adjustment.

With this configuration, it is possible to ensure or adjust the function of the semiconductor using the connection terminal instead of using techniques of, for example, an electric checkup, trimming, or the like.

It is preferable that the semiconductor device of the first aspect of the invention further include: an interconnection connecting the external connection terminal with the first electrode; and a stress-relieving layer provided between the semiconductor substrate and the external connection terminal.

With this configuration, relocated wiring is formed in this semiconductor device by the electrical connection of the first electrode with the external connection terminal via the interconnection.

Therefore, the external connection terminal has wider configurability (i.e., size, shape, arrangement, etc.).

Furthermore, the provision of the stress-relieving layer offers higher connection reliability via the external connection terminal between the semiconductor device and the external apparatus, etc.

It is preferable that the semiconductor device of the first aspect of the invention further include: a sealing resin sealing the connection terminal.

When the connection terminal is sealed with the sealing resin after the connection terminal is used for an electrical checkup or adjustment, it is not possible to perform a subsequent adjustment, or the like, using the connection terminal. Thus, it is possible to increase the reliability of the semiconductor device after the checkup or the adjustment.

Furthermore, when the connection terminal is sealed with the sealing resin after the connection terminal is used for electrical connection with another component, an unexpected short-circuiting in this connection terminal can be prevented, and in addition, bonding strength in this connection terminal can be enhanced.

It is preferable that, in the semiconductor device of the first aspect of the invention, the connection terminal be formed in a columnar shape.

With this configuration, it is possible for the columnar shaped connection terminal, for example, to function as an upper-layer and lower-layer conductive member for electrically conducting a lower layer conductive portion and an upper layer conductive portion, enhancing the configurability of the relocated wiring of the semiconductor device.

A second aspect of the invention provides an electronic component, including: a semiconductor device having: a semiconductor substrate having an active face; a first electrode provided on or above the active face of the semiconductor substrate; an external terminal electrically connected to the first electrode and provided on or above the active face; and a connection terminal provided on or above the active face of the semiconductor substrate; a functional structure disposed on or above a face on an opposite side of the active face of the semiconductor substrate; and a conductive connection portion electrically connecting the functional structure with the connection terminal.

This electronic component connects the semiconductor device with the functional structure via the conductive connection portion utilizing the connection terminal. With this configuration, the semiconductor device and the functional structure are integrated into the electronic component, thus miniaturizing the electronic component.

It is preferable that, in the electronic component of the second aspect of the invention, the conductive connection portion is formed by wire-bonding.

It is preferable that, in the electronic component of the second aspect of the invention, the conductive connection portion have a solder ball.

With this configuration, it is possible to easily obtain a three-dimensional configuration of the semiconductor device and the functional structure.

A third aspect of the invention provides a circuit board, including the above described electronic component. In the circuit board of the third aspect of the invention, the electronic component is packaged on the circuit board.

A fourth aspect of the invention provides an electronic device, including the above described electronic component. In the electronic device of the fourth aspect of the invention, the electronic component is packaged in the electronic device.

Thus, according to the third and fourth aspects of the invention, since a miniaturized electronic component is packaged, high-density packaging can be realized accordingly. Therefore, a circuit board and an electronic device provided with enhanced function can be obtained.

A fifth aspect of the invention provides a manufacturing method for a semiconductor device, including: forming a first electrode on or above an active face of a semiconductor substrate; forming, on or above the active face of the semiconductor substrate, an external connection terminal electrically connected to the first electrode; forming a connection terminal on or above the active face of the semiconductor substrate; and forming any of a gold plated film, a silver plated film, and a palladium plated film on at least one of the external connection terminal and the connection terminal.

The fifth aspect of the invention can suppress diffusion of the metal that forms an external connection terminal and a connection terminal as in the case in which a nickel layer or the like is used.

Therefore, necessity for additional process of thinly removing the top surface is eliminated, thus preventing a decrease in manufacturing efficiency.

It is preferable that, in the manufacturing method for a semiconductor device of the fifth aspect of the invention, any of the gold plated film, the silver plated film, and the palladium plated film be formed by electroless plating.

Thus, the manufacturing method for a semiconductor device of the fifth aspect of the invention can realize a high-density interconnection because there is no need for an interconnection for electroplating.

### BRIEF DESCRIPTION OF THE DRAWINGS

FIG. 1 is a cross-sectional view of an embodiment of a semiconductor device according to this invention.

FIG. 2 is a schematic plan view of the semiconductor device of FIG. 1.

FIGS. 3A to 3D are cross-sectional views for explanation of a manufacturing method for the semiconductor device of FIG. 1.

FIG. 4 is a perspective view for explanation of a manufacturing method for the semiconductor device of FIG. 1.

FIG. 5 is a perspective view of an embodiment of an electronic component according to this invention.

FIG. 6 is a cross-sectional view of another embodiment of a semiconductor device according to this invention.

FIG. 7 is a perspective view of an example of an electronic device in which an electronic component according to this invention is packaged.

### DESCRIPTION OF EXEMPLARY EMBODIMENTS

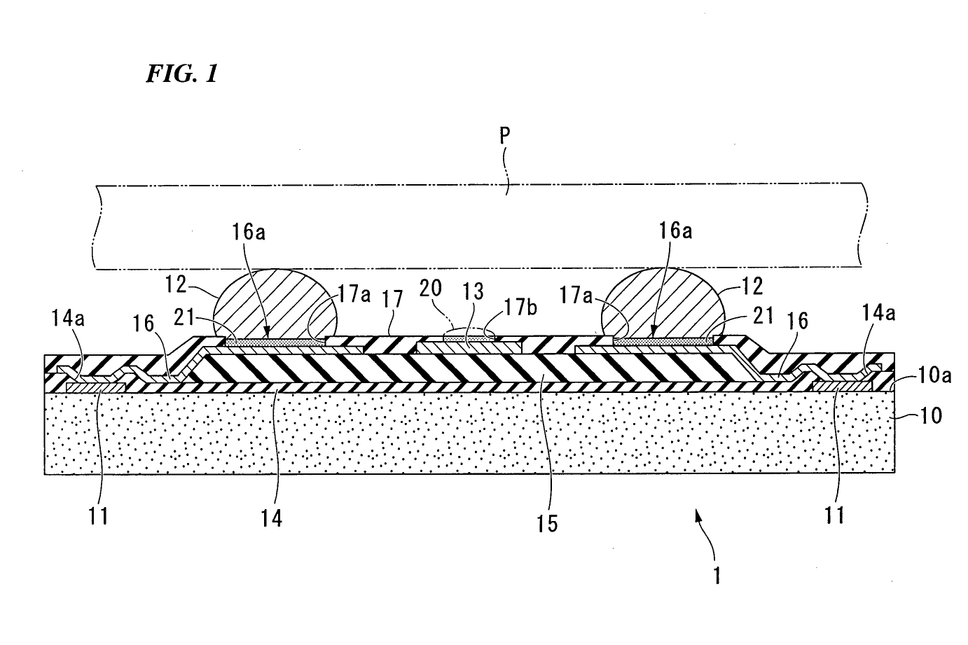

Embodiments of a semiconductor device, a manufacturing method for a semiconductor device, an electronic component, a circuit board, and an electronic device according to this invention will be described with reference to FIGS. 1 to 7.

Semiconductor Device

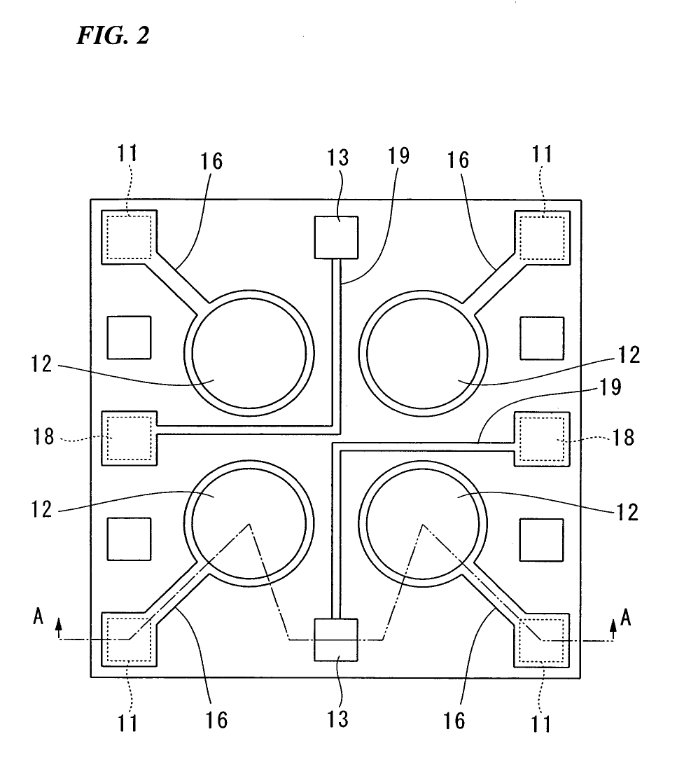

FIGS. 1 and 2 show an embodiment of a semiconductor device according to this invention.

In FIGS. 1 and 2, reference numeral 1 denotes a semiconductor device including a wafer level CSP (W-CSP) configuration.

FIG. 1 is a cross-sectional view taken along the line A-A in a schematic plan view of FIG. 2.

As shown in FIG. 1, the semiconductor device 1 includes: a silicon substrate 10 (semiconductor substrate); a first electrode 1; an external connection terminal 12; a connection terminal 13.

In the silicon substrate 10 (semiconductor substrate), an integrated circuit (not shown) including semiconductor elements such as a transistor and a memory element is formed.

The first electrode 11 is provided on or above an active face 10a of the silicon substrate 10, that is, the side on which the integral circuit is formed.

The external connection terminal 12 is electrically connected to the first electrode 11 and provided on or above the active face 10a.

The connection terminal 13 is provided on or above the active face 10a.

The first electrode 11 is formed by directly conducting to the integrated circuit of the silicon substrate 10.

As shown in FIG. 2, for example, a plurality of the first electrodes 11 are arrayed in the periphery of the rectangular silicon substrate 10.

On the active face 10a, as shown in FIG. 1, a first insulating layer 14 functioning as a passivation film is formed.

In the first insulating layer 14, an opening 14a is formed above the first electrode 11.

In this configuration, the first electrode 11 is outwardly exposed in the opening 14a.

On the first insulating layer 14, a stress-relieving layer 15 made of an insulating resin is formed while avoiding the region of the first electrode 11 and a second electrode 18 (described later), and the region therefor in this embodiment at the center of the silicon substrate 10.

An interconnection 16 is connected to the first electrode 11 in the opening 14a of the insulating layer 14.

The interconnection 16 is used for relocation of an electrode of the integrated circuit.

As shown in FIG. 2, the interconnection 16 is formed to extend from the first electrode 11 arranged in the periphery of the silicon substrate 10 toward the central portion, and to extend from the upper surface of the first electrode 11 toward the upper surface of the stress-relieving layer 15 as shown in FIG. 1.

The interconnection 16 connects between the first electrode 11 of the silicon substrate 10 and the external connection terminal 12 to be described later. Hence, it is generally referred to as relocated wiring.

In order to arrange the region of the electrode 11 of the silicon substrate 10 which is often tightly designed, in a physically-displaced relationship with the region of the rough-pitched external connection terminal 12 which is used for board packaging, the relocated wiring is important.

On or above the active face 10a of the silicon substrate 10, a second insulating layer 17 is formed and covers the interconnection 16, the stress-relieving layer 15, and the first insulating layer 14.

The second insulating layer 17 is made of a solder resist and has heat resistance.

In the second insulating layer 17, an opening 17a is formed on the interconnection 16 formed on the stress-relieving layer 15.

In this configuration, the interconnection 16 is outwardly exposed in the opening 17a.

On the interconnection 16 exposed in the opening 17a, a connection portion 16a (connection terminal) with the external connection terminal 12 is provided.

In the connection portion 16a, a silver plated film 21 is formed on the copper-filmed interconnection 16.

The type of the plated film 21 is selected from a silver plated film and a palladium plated film.

The external connection terminal 12 is formed, for example, as a raised portion of solder (a solder-ball bump).

The external connection terminal 12 is electrically connected to a printed wiring board P (circuit board) as an external device which is shown with a double-dot chain line in FIG. 1.

In this configuration, the integrated circuit (semiconductor element) formed on the silicon substrate 10 is electrically connected to the printed wiring board P via the first electrode 11, the interconnection 16 as relocated wiring, and the external connection terminal 12.

In the integrated circuit formed on the silicon substrate 10, the second electrode 18 is formed in addition to the first electrode 11, as shown in FIG. 2.

The second electrode 18 is used for outputting a signal to drive a functional structure other than the printed wiring board P, or for electrically performing maintenance such as various functional checkups and adjustments of the integrated circuit.

In this embodiment, as in the case of the first electrode 11, the second electrode 18 is connected to relocated wiring 19.

The relocated wiring 19 is connected to the connection terminal 13 exposed outwardly.

The connection terminal 13 is a pad-shaped terminal for electrical or mechanical connection.

The connection terminal 13 is used mainly as a terminal for outputting an output signal for the second electrode 18 to drive a functional structure.

In this case, the connection terminal 13 is suitably utilized in the configuration in which the semiconductor device 1 of this embodiment is connected to a functional structure other than the printed wiring board P.

As described above, the connection terminal 13 may be used for the second electrode 18 to electrically perform various functional checkups and adjustments of the integrated circuit.

In this case, the connection terminal 13 is electrically connected with a checkup or adjustment probe, or the like.

At this time, a checkup or adjustment probe may be simultaneously connected to the external connection terminal 12 to electrically perform various functional checkups and adjustments in cooperation with the connection terminal 13.

After various functional checkups and adjustments of the integrated circuit, for example, the connection terminal 13 is sealed with a sealing resin 20 made of epoxy resin, or the like, as shown with a double-dot chain line in FIG. 1.

Thus, the connection terminal temporarily used for the functional checkup or adjustment is secluded from the external environment subsequent to the sealing.

Therefore, it is possible to seclude the connection terminal from situations that may deteriorate the reliability of the semiconductor element.

The first electrode 11, the second electrode 18, and the connection terminal 13 can be formed of titanium (Ti), titanium nitride (TiN), aluminum (Al), copper (Cu), or an alloy of these.

In this embodiment, the electrodes 11 and 18 are formed of Al.

In this embodiment, the connection terminal 13 is formed by forming, as the plated film, a silver plated film on a Cu film.

The interconnection 16 and the relocated wiring 19 can be formed of gold (Au), copper (Cu), silver (Ag), titanium (Ti), tungsten (W), titanium tungsten (TiW), titanium nitride (TiN), nickel (Ni), nickel vanadium (NiV), chromium (Cr), aluminum (Al), palladium (Pd), or the like.

In this embodiment, the interconnection 16 and the relocated wiring 19 are formed of a Cu film.

The interconnection 16 and the relocated wiring 19 may have a single-layer configuration of one of the above materials, or a laminated-layer configuration obtained by combining a plurality of the above materials.

The interconnection 16 and the relocated wiring 19 are made of the same material, because they are generally formed in the same process.

The first insulating layer 14 and the second insulating layer 17 can be formed from a resin such as a polyimide resin, a modified silicone polyimide resin, an epoxy resin, a modified silicone epoxy resin, an acrylic resin, a phenol resin, a benzocyclobutene (BCB), or a polybenzoxazole (PBO).

The first insulating layer 17 can be formed from an inorganic insulating material such as silicon oxide (SiO₂) and silicon nitride (Si₃N₄).

Manufacturing Method for Semiconductor Device

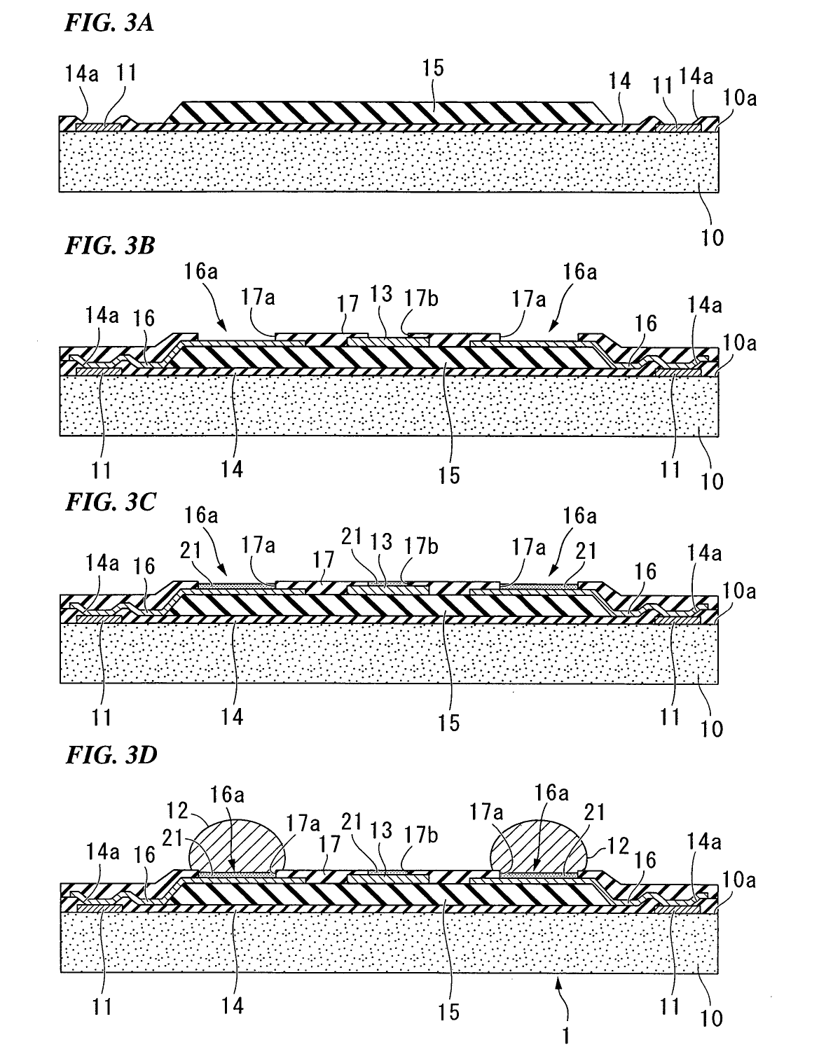

Next, a manufacturing method for the semiconductor device 1 with the above configuration will be described with reference to FIGS. 3A to 3D.

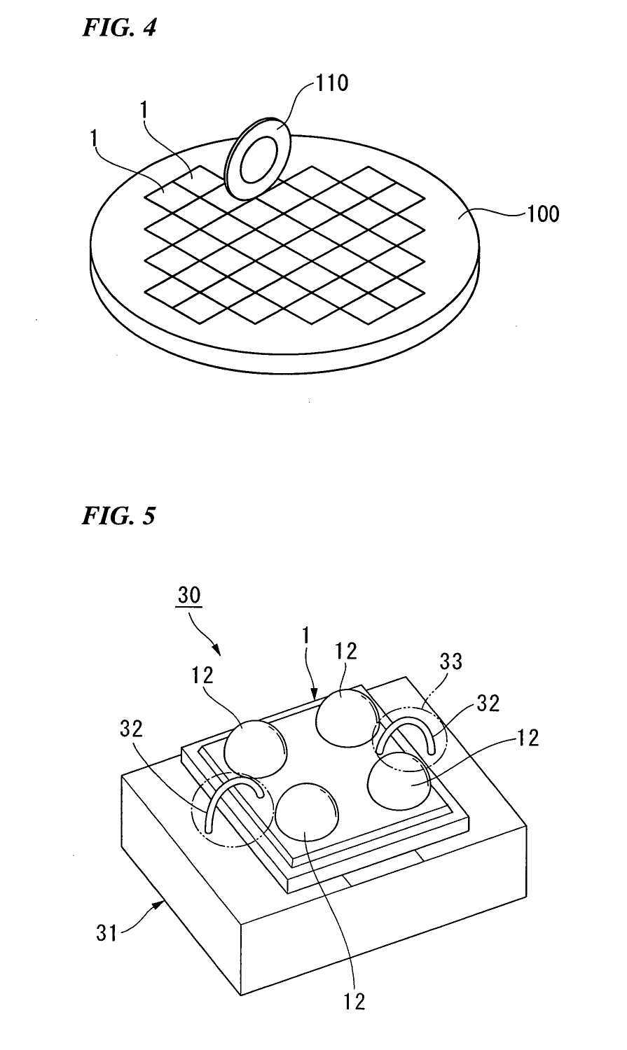

In this embodiment, as shown in FIG. 4, the semiconductor devices are formed simultaneously on the same silicon wafer 100 (substrate). The silicon wafer 100 is then diced (cut) into individual semiconductor devices 1 to obtain the individualized semiconductor device 1.

In FIGS. 3A to 3D, a manufacturing method for only one silicon semiconductor device 1 is shown for a simplified description.

In the following description, the silicon substrate 10 corresponds to the silicon wafer 100.

First, as shown in FIG. 3A, in a region of the active face 10a of the silicon substrate 10, on which a conductive portion for the integrated circuit will be formed, a first electrode 11 and a second electrode 18 (not shown in FIG. 3A, see FIG. 2) are formed.

Next, the first insulating layer 14 covering the first electrode 11 and the second electrode 18 is formed on the silicon substrate 10. Then a resin layer (not shown) is formed to cover the first insulating layer 14.

Next, the resin layer is patterned by known methods of photolithography and etching, the stress-relieving layer 15 is formed in a predetermined shape in the central region of the silicon substrate 10, i.e., in a shape avoiding the region directly above the first electrode 11 and the second electrode 18.

The insulating material in the region covering the first electrode 11 and the second electrode 18 is removed by known methods of photolithography and etching to form the opening 14a.

Thereby, the first electrode 11 and the second electrode 18 are exposed in the opening 14a.

Next, as shown in FIG. 3B, the interconnection 16 connected to the first electrode 11 is formed, and the relocated wiring 19 connected to the second electrode 18 is formed.

The method for forming the interconnection 16 and relocated wiring 19 will be described.

First, a layer is formed by sequentially sputtering conductive materials such as Cu such that the layer is conductive with the first electrode 11 and the second electrode 18 in the opening 14a.

The layer is then patterned according to the shapes of the interconnection 16 and relocated wiring 19, and subsequently Cu is laminated on the obtained pattern by plating.

An end of the relocated wiring 19, that is, as shown in FIG. 2, an end opposite to the second electrode 18 is formed as a connection terminal portion in the relocated wiring 19 by patterning in a pad shape.

Next, the second insulating layer 17 covering the interconnection 16, the relocated wiring 19, and the connection terminal 13 is formed.

Then, an insulating material covering a part of the interconnection 16, that is, a region opposite to the first electrode is removed by known methods of photolithography and etching to form the opening 17a.

The interconnection 16 is exposed in the opening 17a to form the connection portion 16a.

At the same time, an insulating material covering the connection terminal 13 is also removed to form an opening 17b, thus exposing the connection terminal 13 in the opening 17b.

Next, the silicon substrate 10 is immersed in an electroless Ag plating bath heated to a predetermined temperature.

Then, as shown in FIG. 3C, the second insulating layer 17 functions as a mask and a silver plated film 21 is formed by plating on the copper film of the connection portion 16a and the connection terminal 13 exposed from the openings 17a and 17b.

Thus, with the formation of the silver plated film 21 on the surface of the copper film, the electrical connectivity or the junction performance in wire-bonding is increased.

Subsequently, as shown in FIG. 3D, a solder ball of Pb-free solder, or the like, is disposed on the connection portion 16a on the interconnection 16 (silver plated film 21) exposed in the opening 17a, to form the external connection terminal 12.

The external connection terminal 12 may be formed by printing solder paste on the interconnection 16, instead of by disposing a solder ball.

As shown in FIG. 4, a dicing device 110 is then used to dice (cut) the silicon wafer 100 (substrate) into individual semiconductor devices 1 to obtain a semiconductor device 1.

In the semiconductor device 1 thus obtained, especially in the case in which the connection terminal 13 is used for checkup or adjustment (for maintenance), that is, in the case in which the second electrode 18 is used for electrically performing various functional checkups or adjustments of the integrated circuit, the second electrode 18 utilizes this connection terminal 13 to perform maintenance such as functional checkups or adjustments of the integrated circuit.

Specifically, the function of the integrated circuit is ensured or adjusted by IC probe checkup, trimming (fuse cutting), or the like, performed simultaneously with the probe checkup.

In the case in which the connection terminal 13 is used only for a functional checkup or adjustment of the integrated circuit, the connection terminal 13 is sealed with the sealing resin 20 as described above after the completion of the checkup or adjustment.

In this embodiment, when the connection terminal 13 is configured for a functional checkup or adjustment of the integrated circuit, the quality stability of the semiconductor device 1 is secured and the reliability thereof is increased.

In other words, since the external connection terminal 12 is used for packaging by the user, it is necessary to generally widen the terminal pitch thereof. In this case, all the terminals may not be drawn as external connection terminals from the integrated circuit (IC) due to limitations in circuit design.

In contrast to this, this embodiment is provided with the connection terminal 13 that is not used for packaging by the user in addition to the external connection terminal 12. The connection terminal 13 is utilized for a functional checkup or adjustment of the integrated circuit, which can lessen the limitations in circuit design with respect to the external connection terminal 12 and increase the configurability of design.

In this invention, the connection terminal 13 does not interfere with the region of the external connection terminal 12. Therefore, as described above, the connection terminal 13 may be extended from the second electrode 18 to any region via the relocated wiring 19, the only requirement being that the region does not impair the degree of configurability of design.

The connection terminal 13 may be arranged on any position on the relocated wiring 19, and in addition, may be directly disposed on the second electrode 18 without using the relocated wiring 19.

The connection terminal 13 may be formed directly in a part of the relocated wiring 19, as described above. The connection terminal 13 may be formed with a pad, or the like, independently of the relocated wiring 19 or the second electrode 18.

In the case in which the connection terminal 13 is used as a terminal for adjustment, a terminal for data writing, a terminal which must not be exposed to the user, or the like, the connection terminal 13 of this embodiment may be sealed with a sealing resin 20 especially after the completion of the functional checkup or adjustment, preventing a subsequent adjustment, or the like, through the connection terminal 13.

Therefore, the state at the completion of the checkup or the adjustment can be kept as it is. It is possible to secure the quality stability of the semiconductor device 1 and increase the reliability thereof.

Electronic Component

All the connection terminals 13 obtained as above may be used for a functional checkup or adjustment of the integrated circuit. However, only some of them may be used for a functional checkup or adjustment of the integrated circuit and the others may be utilized for connection to functional structures other than the printed wiring board P.

All the connection terminals 13 may be utilized in connecting to other functional structures.

That is, an electronic component of this invention can be constituted by integrating the semiconductor device 1 into a functional structure.

An electronic component of this invention using the above semiconductor device 1 will be described.

FIG. 5 is a perspective view showing an embodiment of an electronic component of this invention. In FIG. 5, reference numeral 30 denotes the electronic component.

This electronic component 30 includes the semiconductor device 1 and a functional structure 31.

As the functional structure 31, any of various types of functional structures can be used without particular limitation.

Specifically, a crystal oscillator, a piezoelectric oscillator, a piezoelectric tuning fork, a surface acoustic wave (SAW) element, a MEMS structure, a semiconductor device other than the semiconductor device 1, any of other electronic component structures of various types, or the like, can be used.

The semiconductor device 1 is used, in particular, for driving this functional structure 31.

That is, in this embodiment, the second electrode 18 in the semiconductor device 1 has a function to output an output signal to drive the functional structure 31. Therefore, the connection terminal 13 connected to the second electrode 18 is electrically connected to a connection terminal (not shown) on or above the functional structure 31.

In the electronic component 30 of this invention, the semiconductor device 1 is packaged on the upper face of the functional structure 31, and fixed thereon with an adhesive, or the like.

The semiconductor device 1 is packaged such that the active face 10a thereof faces outward. The functional structure 31 is thereby joined on the opposite side of the active face 10a of the semiconductor device 1.

With this configuration, the connection terminal 13 and the connection terminal of the functional structure 31 are connected by a conductive connection portion on the respective upper faces of the functional structure 31 and the semiconductor device 1.

As a conductive connection portion, wire-bonding by gold wire 32 is simple and preferable.

The packaging technique, however, is not limited to this. Other known packaging techniques such as wire connection by soldering, beam lead, and tape automated bonding (TAB) can also be adopted.

Since this wire-bonding by the gold wire 32 is applied on or above the active face 10a of the semiconductor device 1, the gold wire 32 is formed on the same face as the external connection terminal 12 of the semiconductor device 1, as shown in FIG. 5.

When the electronic component 30 is packaged in the printed wiring board P, the electronic component 30 is packaged by the external connection terminal 12. Therefore, the gold wire 32 faces the printed wiring board P.

In this embodiment, in order to prevent the gold wire 32 from abutting on the printed wiring board P especially when packaging, the height of this gold wire (the height of the bonding wire), to be specific, the top height of the gold wire 32 (the distance from the active face 10a to the top of the gold wire 32) is sufficiently lower than the height of the external connection terminal 12 (the distance from the active face 10a to the top of the external connection terminal 12).

By this means, interference of the gold wire 32 with the printed wiring board P (external apparatus) is prevented when the electronic component 30 is connected to the printed wiring board P via the external connection terminal 12.

Thus, a desirable connection is obtained without bringing about short-circuiting, or the like, between the external connection terminal 12 and the gold wire 32.

It is preferable that the connection terminal 13 be sealed with a sealing resin 33 as shown with a double-dot chain line in FIG. 5 after the connection terminal 13 of the semiconductor device 1 and the connection terminal of the functional structure 31 are wire-bonded.

By this means, it is possible to increase the bonding strength of the gold wire 32 with respect to the connection terminal 13.

Since the connection terminal 13 and the gold wire 32 are coated with a resin, it is possible to also decrease the damage to the connection section configuration caused in subsequent processes, and tremendously improve even connection reliability.

In the manufacturing method for electronic component 30 of this embodiment, the external connection terminal 12 is formed on the connection portion 16a before dicing the silicon wafer to obtain individual semiconductor devices 1. This manufacturing method for electronic component 30, however, is not limited to this. The external connection terminal 12 may be formed after a silicon wafer is diced to obtain individual semiconductor devices 1 without forming an external connection terminal 12, and then wire-bonding is performed between the individual semiconductor device 1 and the functional structure 31.

It is known that when the copper film of the connection portion 16a and the connection terminal 13 is plated with electroless nickel-phosphorus and gold, a phosphorus-enriched layer is formed on the surface of the gold layer, or nickel compounds (mainly a nickel hydroxide) deposit, causing interlayer delamination at an interface between nickel and solder in the application of solder on the plated film.

In contrast, in this embodiment, the silver plated film 21 is formed on the copper film to suppress such disadvantages. Therefore, it is possible to increase the reliability of a functional structure after packaging via wire-bonding or soldering.

In this embodiment, the necessity for an additional process of removing the top surface of the gold layer is eliminated as is the case in which nickel or phosphor is used, thus contributing to the improvement of manufacturing efficiency.

In this embodiment, the plated film 21 is formed by electroless plating. Therefore, there is no need for an interconnection for electroplating, and thus it is possible to realize a high-density interconnection.

In this embodiment, the connection terminal 13 is provided in addition to the external connection terminal 12. Thus, this semiconductor device 1 and the functional structure 31 can be integrated to form the electronic component 30 by mechanically or electrically connecting the semiconductor device 1 to the functional structure 31 using the connection terminal 13. Therefore, it is possible to miniaturize the electronic component 30.

The stress-relieving layer 15 is provided between the silicon substrate 10 and the external connection terminal 12. Thus, for example, even if a stress due to pressure or heat develops in the external connection terminal 12 when the semiconductor device 1 is connected to the external apparatus such as the printed wiring board P via the external connection terminal 12, the stress-relieving layer 15 relieves the stress, thereby preventing problems such as a break in the wire.

Therefore, it is possible to improve the connection reliability between the external connection terminal 12 and the external apparatus.

Since, in the electronic component 30 of this embodiment, the semiconductor device 1 and the functional structure 31 are connected by wire-bonding utilizing the connection terminal 13, the semiconductor device 1 and the functional structure 31 are integrated easily only with known techniques to configure an electronic component with a three-dimensional configuration. Therefore, it is possible to sufficiently miniaturize the component as an aggregate, and in addition, to reduce the cost thereof.

This embodiment describes a configuration with an electrical connection to the connection terminal in which wire-bonding is used. However, the configuration is not limited to this. Connection may be made by a packaging method involving a lead such as TAB or chip on flexible (COF).

This applies to any embodiment below.

While exemplary embodiments of the invention have been described above with reference to the accompanying drawings. However, this invention is not limited to these.

Shapes, combinations or the like of the constituent members shown in above are merely examples, and various modifications based on design requirements or the like can be made without departing from the spirit or scope of the invention.

For example, the above-described embodiments describe the silver plated film 21 formed on the copper film. However, the similar action and effect can be obtained even when a film of a metal that has oxidation resistance and capable of metal junction, such as gold or palladium, or a composite film of silver and another metal is adopted instead of the silver plated film 21.

In the embodiment shown in FIG. 5, wire-bonding is utilized in the connection terminal 13 for electrical connection. However, the connection terminal 13 may be used only for a mechanical connection.

Specifically, the connection terminal 13 may be used as a wire-bonding configuration in which the connection terminal 13 is formed by using a metal, or the like, as a land electrically independent of the integrated circuit formed on the silicon substrate 10, with the only actualization of mechanically connecting the functional structure 31 and the silicon substrate 10.

Specifically, in the case in which a suspension configuration is adopted in which the semiconductor device 1 is suspended with respect to the functional structure 31, in the case in which it is difficult to use an adhesive or sufficient junction strength cannot be obtained only with an adhesive, or the like, a mechanical connection with a wire-bonding configuration utilizing the connection terminal 13 may be adopted.

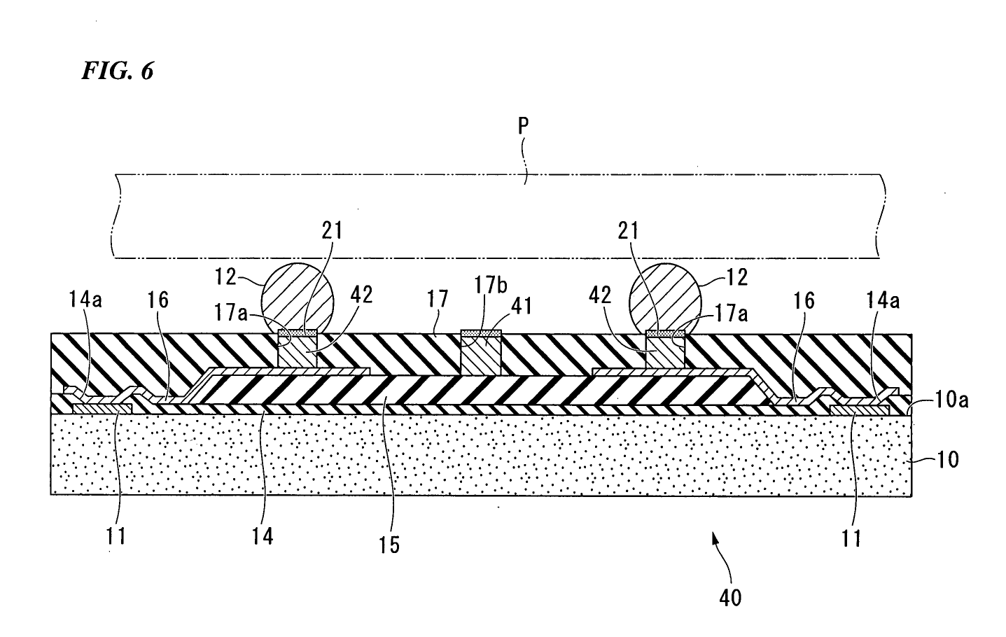

For the configuration of the connection terminal 13, a columnar (post) configuration shown in FIG. 6 may be adopted instead of the pad configuration shown in FIG. 1.

In a semiconductor device 40 shown in FIG. 6, a connection terminal 41 is formed of, for example, copper in a columnar (post) shape. The upper face thereof working as a connection face is plated with a silver plated film 21 (or palladium plated film, etc.) for prevention of surface rust and for the improvement of bonding.

In this semiconductor device 40, a post 42 is formed also between the external connection terminal 12 and the interconnection 16. The post 42 (connection portion) is formed by the same process as that for the connection terminal 41.

By this means, the external connection terminal 12 and the interconnection 16 is electrically connected on or above the upper face of the second insulating layer 17 via the silver plated film 21 and the post 42.

With regard to this configuration, the columnar connection terminal 41 functions as an upper-layer and lower-layer conductive member for electrically conducting, for example, the second electrode 18 as a conductive portion of the lower layer or the relocated wiring 19 and a conductive layer (not shown) formed in the upper layer (the layer above the second insulating layer 17) as required. Thus, it is possible to enhance the configurability of relocated wiring in the overall semiconductor device 40.

Circuit Board and Electronic Device

A circuit board of this invention is formed by packaging the electronic component 30 in, for example, the printed wiring board P shown with a double-dot chain line in FIG. 1.

That is, a circuit board as an embodiment of this invention is formed by electrically connecting the external connection terminal 12 of the semiconductor device 1 (40) in the electronic component 30 to a conductive section of the printed wiring board P.

This circuit board is packaged with the miniaturized electronic component 30, allowing high-density packaging accordingly. Therefore, function of the circuit board can be enhanced.

An electronic device of this invention is also packaged with the electronic component.

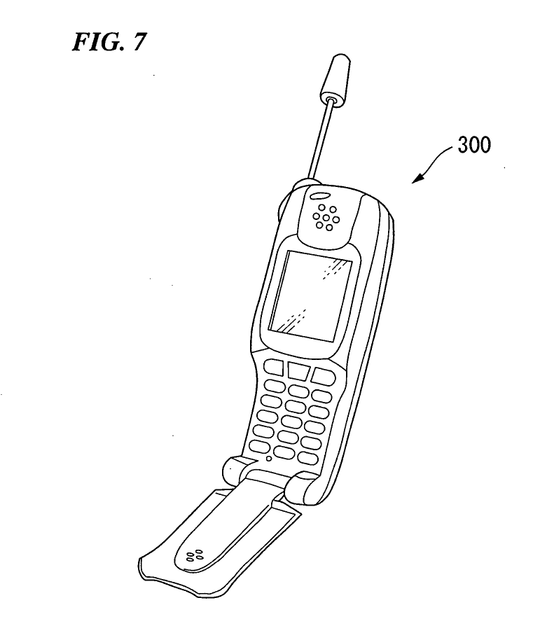

Specifically, a portable telephone 300 shown in FIG. 7 is an example of an electronic device packaged with the electronic component 30.

This electronic device is also packaged with the miniaturized electronic component, allowing high-density packaging accordingly. Therefore, it is possible to enhance the function of the electronic device and contribute to a lower cost resulting from the improvement in manufacturing efficiency.

Other electronic devices to which this invention is applicable include, for example, ICs card, video cameras, personal computers, head-mount displays, projectors, facsimile apparatuses, digital cameras, portable TVs, DSP devices, PDAs, and electronic notebooks.

What is claimed is:

1. A semiconductor device, comprising:
a semiconductor substrate having an active face;
a first electrode provided on or above the active face of the semiconductor substrate;
an external connection terminal electrically connected to the first electrode and provided on or above the active face of the semiconductor substrate; and
a connection terminal provided on or above the active face of the semiconductor substrate, wherein
any of a gold plated film, a silver plated film, and a palladium plated film is formed on at least one of the external connection terminal and the connection terminal.

2. The semiconductor device according to claim 1, wherein any of the gold plated film, the silver plated film, and the palladium plated film are formed by electroless plating.

3. The semiconductor device according to claim 1, further comprising:
relocated wiring provided on or above the active face and electrically connecting the first electrode with the external connection terminal.

4. The semiconductor device according to claim 1, further comprising:
a second electrode provided on or above the active face of the semiconductor substrate and electrically connected with the connection terminal.

5. The semiconductor device according to claim 1, wherein the connection terminal is used for an electrical checkup or adjustment.

6. The semiconductor device according to claim 1, further comprising:
an interconnection connecting the external connection terminal with the first electrode; and
a stress-relieving layer provided between the semiconductor substrate and the external connection terminal.

7. The semiconductor device according to claim 1, further comprising:
a sealing resin sealing the connection terminal.

8. The semiconductor device according to claim 1, wherein the connection terminal is formed in a columnar shape.

9. An electronic component, comprising:
a semiconductor device having: a semiconductor substrate having an active face; a first electrode provided on or above the active face of the semiconductor substrate; an external terminal electrically connected to the first electrode and provided on or above the active face; and a connection terminal provided on or above the active face of the semiconductor substrate;
a functional structure disposed on or above a face on an opposite side of the active face of the semiconductor substrate; and
a conductive connection portion electrically connecting the functional structure with the connection terminal.

10. The electronic component according to claim 9, wherein the conductive connection portion is formed by wire-bonding.

11. The electronic component according to claim 9, wherein the conductive connection portion has a solder ball.

12. A circuit board comprising the electronic component according to claim 9, wherein the electronic component is packaged on the circuit board.

13. An electronic device comprising the electronic component according to claim 9, wherein the electronic component is packaged in the electronic device.

14. A manufacturing method for a semiconductor device, comprising:
forming a first electrode on or above an active face of a semiconductor substrate;
forming, on or above the active face of the semiconductor substrate, an external connection terminal electrically connected to the first electrode;
forming a connection terminal on or above the active face of the semiconductor substrate; and
forming any of a gold plated film, a silver plated film, and a palladium plated film on at least one of the external connection terminal and the connection terminal.

15. The manufacturing method for a semiconductor device according to claim 14, wherein any of the gold plated film, the silver plated film, and the palladium plated film are formed by electroless plating.
